(19) United States
(12) Patent Application Publication
(10) Pub. No.: US 2021/0359243 A1
(43) Pub. Date: Nov. 18, 2021

(54) OLED PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xingyong ZHANG, Wuhan, Hubei (CN)

(21) Appl. No.: 16/322,955

(22) PCT Filed: Jan. 24, 2019
(86) PCT No.: PCT/CN2019/073037

§ 371 Date: Feb. 3, 2019

(30) Foreign Application Priority Data
Sep. 28, 2018 (CN) 2018111142938.1

(51) Int. Cl. H01L 51/52; H01L 51/56

(52) U.S. Cl. CPC H01L 51/525; H01L 2251/301; H01L 51/56

(57) ABSTRACT

An OLED panel and a manufacturing method thereof are provided, the OLED panel includes a light emitting substrate, and at least one set of encapsulating film disposed on the light emitting substrate. The encapsulating film includes a first inorganic layer disposed on the light emitting substrate; an inorganic dam disposed at an edge region of the first inorganic layer; an organic layer disposed on the first inorganic layer and surrounded by the inorganic dam; and a second inorganic layer disposed on the organic layer and covering the first inorganic layer, the organic layer and the inorganic dam.

### FIELD OF INVENTION

The present application relates to a field of display technologies, and in particular, to an organic light emitting diode (OLED) panel and a manufacturing method thereof.

### BACKGROUND OF INVENTION

Organic light emitting diodes (OLEDs) are used as a current type of light emitting device. Because OLED has advantages, such as self-illumination, rich colors, fast response times, wide viewing angles, and light weight, it can be made into a flexible display screen and has received extensive attention.

However, OLED devices are very sensitive to moisture and oxygen. Therefore, it is often necessary to encapsulate the OLED devices. The existing encapsulation method still makes an edge of the OLED devices easy to be intruded by moisture and oxygen, which causes, such as electrode oxidation, poor chemical reaction of organic materials or black spots, resulting in decreased service life of the OLED devices.

Therefore, it is necessary to provide an OLED panel and a manufacturing method thereof to solve the problems of the conventional art.

Technical problem: the technical problem mainly solved by the present application is how to improve moisture and oxygen barrier capability of the OLED panel, thereby prolonging the service life of the OLED panel.

### SUMMARY OF INVENTION

The embodiment of the present application is to provide an organic light emitting diode (OLED) panel, which can improve the moisture and oxygen barrier capability of the OLED panel, thereby prolonging the service life of the OLED panel.

In a first aspect, the application provides an organic light-emitting diode (OLED) panel, including:

a light emitting substrate, and at least one set of encapsulating film disposed on the light emitting substrate;

wherein the encapsulating film includes a first inorganic layer disposed on the light emitting substrate, an inorganic dam disposed at an edge region of the first inorganic layer, an organic layer disposed on the first inorganic layer and surrounded by the inorganic dam, and a second inorganic layer disposed on the organic layer and covering the first inorganic layer, the organic layer and the inorganic dam;

wherein the inorganic dam includes a plurality of sidewalls, the sidewalls include a first sidewall and a second sidewall opposite to each other, and a third sidewall and a fourth sidewall separately disposed on two opposite sides of the first sidewall, wherein the third sidewall and the fourth sidewall are disposed opposite to each other;

wherein a material of the inorganic dam is selected from a group consisting of silicon nitride, silicon carbonitride, and silicon oxide.

In the OLED panel according to the present application, wherein the first sidewall is connected to the third sidewall and the fourth sidewall, and the second sidewall is connected to the third sidewall and the fourth sidewall, such that the inorganic dam surrounds the organic layer at the edge region of the first inorganic layer.

In the OLED panel according to the present application, wherein the inorganic dam further includes a first connecting arm, a second connecting wall, a third connecting arm and a fourth connecting arm;

the first connecting arm is connected to the first sidewall and the third sidewall;

the second connecting arm is connected to the first sidewall and the fourth sidewall;

the third connecting arm is connected to the second sidewall and the third sidewall; and

the fourth connecting arm is connected to the second sidewall and the fourth sidewall.

In the OLED panel according to the present application, wherein any one of the sidewalls includes a body portion and two bent portions disposed at both ends of the body portion; and

wherein at least one opening is formed in the bent portions of the first sidewall and the bent portions of the second sidewall; and/or

at least one opening is formed in the bent portions of the third sidewall and the bent portions of the fourth sidewall.

In the OLED panel according to the present application, wherein a distance between the bent portion of one of the sidewalls and a center point of the light emitting substrate is different from a distance between the bent portion of another adjacent one of the sidewalls and the center point of the light emitting substrate.

In the OLED panel according to the present application, wherein a material of the organic layer is selected from a group consisting of acrylic, epoxy, and silicone.

In a second aspect, the present application provides an organic light-emitting diode (OLED) panel, including:

a light emitting substrate, and at least one set of encapsulating film disposed on the light emitting substrate;

wherein the encapsulating film includes a first inorganic layer disposed on the light emitting substrate, an inorganic dam disposed at an edge region of the first inorganic layer, an organic layer disposed on the first inorganic layer and surrounded by the inorganic dam, and a second inorganic layer disposed on the organic layer and covering the first inorganic layer, the organic layer and the inorganic dam.

In the OLED panel according to the present application, wherein the inorganic dam includes a plurality of sidewalls, the sidewalls include a first sidewall and a second sidewall opposite to each other, and a third sidewall and a fourth sidewall separately disposed on two opposite sides of the first sidewall, wherein the third sidewall and the fourth sidewall are disposed opposite to each other.

In the OLED panel according to the present application, wherein the first sidewall is connected to the third sidewall and the fourth sidewall, and the second sidewall is connected to the third sidewall and the fourth sidewall, such that the inorganic dam surrounds the organic layer at the edge region of the first inorganic layer.

In the OLED panel according to the present application, wherein the inorganic dam further includes a first connecting arm, a second connecting wall, a third connecting arm and a fourth connecting arm;

the first connecting arm is connected to the first sidewall and the third sidewall;

the second connecting arm is connected to the first sidewall and the fourth sidewall;

the third connecting arm is connected to the second sidewall and the third sidewall; and

the fourth connecting arm is connected to the second sidewall and the fourth sidewall.

In the OLED panel according to the present application, wherein any one of the sidewalls includes a body portion and two bent portions disposed at both ends of the body portion; and

wherein at least one opening is formed in the bent portions of the first sidewall and the bent portions of the second sidewall; and/or

at least one opening is formed in the bent portions of the third sidewall and the bent portions of the fourth sidewall.

In the OLED panel according to the present application, wherein a distance between the bent portion of one of the sidewalls and a center point of the light emitting substrate is different from a distance between the bent portion of another adjacent one of the sidewalls and the center point of the light emitting substrate.

In the OLED panel according to the present application, wherein a material of the inorganic dam is selected from a group consisting of silicon nitride, silicon carbonitride, and silicon oxide.

In a third aspect, the present application provides a manufacturing method of an organic light-emitting diode (OLED) panel, including steps of:

providing a light emitting substrate; and

forming at least one set of encapsulating film on the light emitting substrate, wherein the encapsulating film includes a first inorganic layer, an organic layer and a second inorganic layer laminated and stacked on the light emitting substrate, and wherein an edge region of the first inorganic layer is formed with an inorganic dam.

In the manufacturing method according to the present application, wherein the step of forming the at least one set of encapsulating film on the light emitting substrate includes steps of:

forming the first inorganic layer on the light emitting substrate;

forming an inorganic barrier layer on the first inorganic layer;

patterning the inorganic barrier layer to form the inorganic dam at the edge region of the first inorganic layer;

forming the organic layer on the first inorganic layer and corresponding to a region surrounded by the inorganic dam; and

forming the second inorganic layer on the first inorganic layer, the inorganic dam, and the organic layer.

In the manufacturing method according to the present application, wherein the step of patterning the inorganic barrier layer to form the inorganic dam at the edge region of the first inorganic layer includes steps of:

shielding a region of the first inorganic layer except the edge region of the first inorganic layer by a first mask, to form a first inorganic dam at the edge region of the first inorganic layer; and

shielding the first inorganic dam and a region of the first inorganic layer without forming the inorganic dam by a second mask, to form a second inorganic dam at the edge region of the first inorganic layer, wherein the first inorganic dam and the second inorganic dam surround the organic layer to form the inorganic dam.

In the manufacturing method according to the present application, wherein the step of patterning the inorganic barrier layer to form the inorganic dam at the edge region of the first inorganic layer includes step of:

shielding a region of the first inorganic layer except the edge region of the first inorganic layer by a third mask to form the inorganic dam at the edge region of the first inorganic layer.

BENEFICIAL EFFECT: The beneficial effect of the present application is that the inorganic dam is disposed in the edge region of the first inorganic layer to achieve the purpose of improving the moisture and oxygen barrier capability of the OLED panel, thereby prolonging the service life of the OLED panel.

### DRAWINGS

In order to more clearly illustrate the technical solutions in the embodiments or the conventional art, the drawings to be used in the description of the embodiments or the conventional art will be briefly described below. It is apparent that the drawings in the following description are only for some embodiments of the present application. For those of ordinary skill in the art, other drawings may also be obtained from these drawings without paying for creative effort.

FIG. 1 is a schematic cross-sectional view showing an organic light emitting diode (OLED) panel provided by a first embodiment of the present application.

FIG. 2 is a schematic planar view showing an inorganic dam disposed on the OLED panel provided by the first embodiment of the present application.

FIG. 3 is a schematic planar view showing an inorganic dam disposed on an OLED panel provided by a second embodiment of the present application.

FIG. 4 is a schematic planar view showing an inorganic dam disposed on an OLED panel provided by a third embodiment of the present application.

FIG. 5 is a schematic planar view showing an inorganic dam disposed on an OLED panel provided by a fourth embodiment of the present application.

FIG. 6 is a schematic planar view showing an inorganic dam disposed on an OLED panel provided by a fifth embodiment of the present application.

FIG. 7 is a schematic flow chart of a manufacturing method of an OLED device according to the present application.

FIG. 8 is a schematic flow chart of forming at least one encapsulating film on a light emitting substrate in a manufacturing method of an OLED device according to the present application.

FIG. 9 is a schematic structural view of a first mask provided by the first embodiment of the present application.

FIG. 10 is a schematic structural view of a second mask provided by the first embodiment of the present application.

FIG. 11 is a schematic structural view of a first mask provided by the second embodiment of the present application.

FIG. 12 is a schematic structural view of a second mask provided by the second embodiment of the present application.

FIG. 13 is a schematic flow chart of forming a set of encapsulating film on a light emitting substrate in a manufacturing method of an OLED device according to the present application.

FIGS. 14-22 are specifically schematic flowcharts showing a manufacturing method of an OLED panel according to the present application;

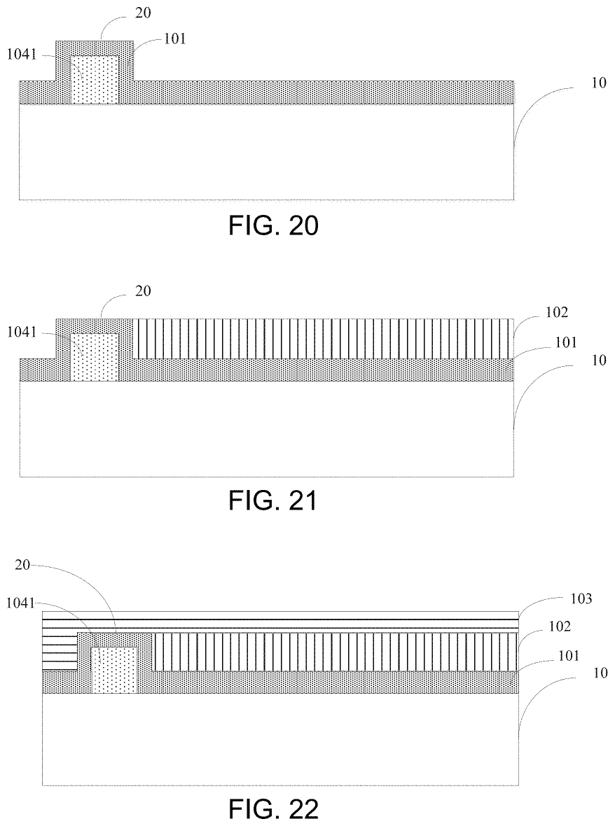

FIG. 23 is a schematic cross-sectional view of an OLED panel provided by the second embodiment of the present application.

### DETAILED DESCRIPTION OF PREFERRED EMBODIMENTS

The following description will be accompanied with the drawings in the embodiments of the present application, the technical solutions in the embodiments of the present application will be clearly and completely described. It is apparent that the described embodiments are only a part of the embodiments of the present application, and not all of them. All other embodiments obtained by a person skilled in the art based on the embodiments of the present application without any creative efforts are within the scope of the present application.

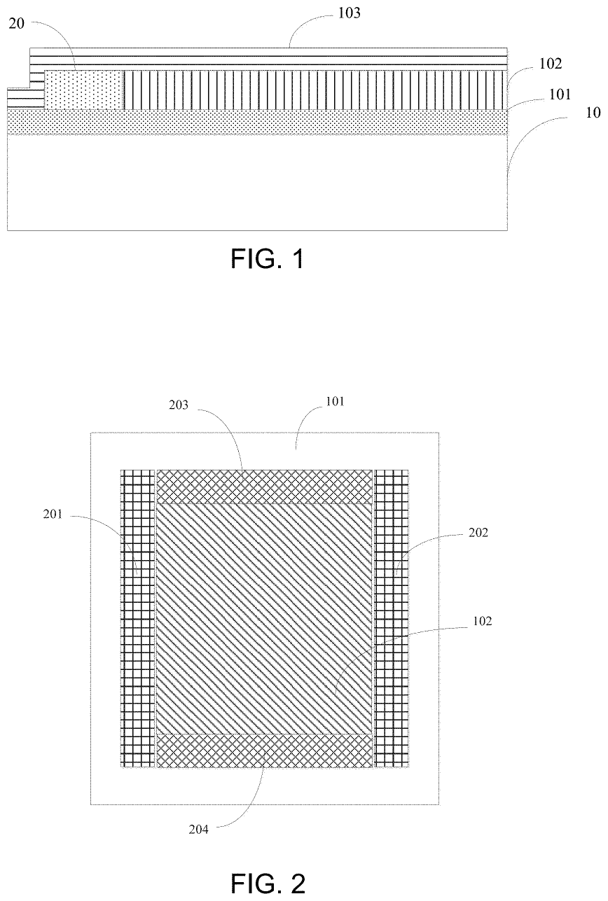

Please refer to FIG. 1. FIG. 1 is a schematic cross-sectional view showing an organic light emitting diode (OLED) panel provided by a first embodiment of the present application.

An embodiment of the present application provides an organic light emitting diode (OLED) panel, including:

alight emitting substrate 10, and at least one set of encapsulating film disposed on the light emitting substrate.

The encapsulating film includes a first inorganic layer 101 disposed on the light emitting substrate 10. An inorganic dam 20 disposed at an edge region of the first inorganic layer 101, an organic layer 102 disposed on the first inorganic layer 101 and the organic layer 102 surrounded by the inorganic dam 20. In a direction that the light emitting substrate 10 forward the organic layer 102, a second inorganic layer 103 is disposed on the organic layer 102 that covers the first inorganic layer 101, the organic layer 102, and the inorganic dam 20.

Specifically, the light emitting substrate 10 may be alight emitting substrate formed with OLED devices, and the light emitting substrate 10 may include various circuit structures and/or may be any kind of substrate structures according to actual requirements. At least one set of encapsulating film is disposed on the light emitting substrate 10. Optionally, it may be a set of encapsulating film, or may be multiple sets of encapsulating film stacked on the light emitting substrate 10. The encapsulating film includes a first inorganic layer 101 disposed on the light emitting substrate 10, and the first inorganic layer 101 can be provided on the light emitting substrate 10 by a chemical vapor deposition process. And then, using a mask, the inorganic dam 20 is then provided on the edge region of the first inorganic layer 101 by a chemical vapor deposition process. The method for disposing the organic layer 102 on the first inorganic layer 101 can be printing a layer of the organic layer 102 on an inner side of the inorganic dam 20 by using an inkjet printing process. A material of the organic layer 102 may be selected from a group consisting of acrylic, epoxy, and silicone, in order to buffer a stress during bending and folding and cover particles. A second inorganic layer 103 provides on the organic layer 102 that covers the first inorganic layer 101, the organic layer 102, and the inorganic dam 20. It should be noted that a material of the first inorganic layer 101 and a material of the second inorganic layer 103 may be the same or different.

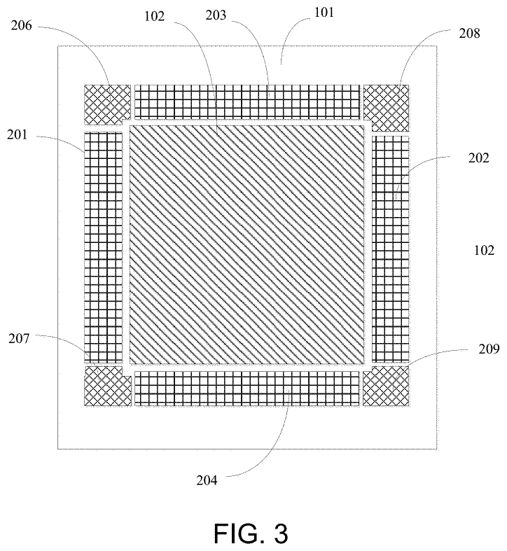

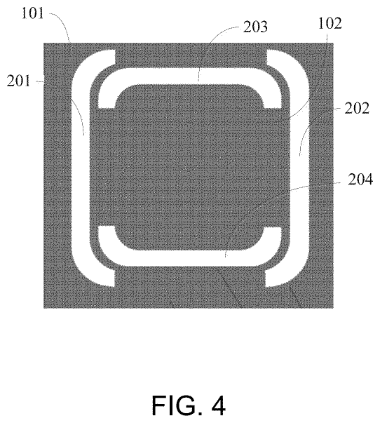

Please refer to FIG. 1 and accompany with FIG. 2 and FIG. 3, FIG. 2 is a schematic planar view showing an inorganic dam disposed on the OLED panel provided by the first embodiment of the present application, and FIG. 3 is a schematic planar view showing an inorganic dam disposed on an OLED panel provided by a second embodiment of the present application.

The inorganic dam includes a plurality of sidewalls. The sidewalls include a first sidewall 201 and a second sidewall 202 are disposed opposite to each other, and a third sidewall 203 and a fourth sidewall 204 are respectively disposed on opposite sides of the first sidewall. The third sidewall 203 and the fourth sidewall 204 are disposed opposite to each other.

The first sidewall 201 is connected to the third sidewall 203 and the fourth sidewall 204. The second sidewall 202 is connected to the third sidewall 203 and the fourth sidewall 204 to surround the organic layer 102 disposed on the first inorganic layer 101 at an edge region of the first inorganic layer 101.

The inorganic dam 20 further includes a first connecting arm 206, a second connecting wall 207, a third connecting arm 208, and a fourth connecting arm 209. The first connecting arm 206 connects the first sidewall 201 and the third sidewall 203. The second connecting wall 207 connects the first sidewall 201 and the fourth sidewall 204. The third connecting arm 208 connects the second sidewall 202 and the third sidewall 203. The fourth connecting arm 209 connects the second sidewall 202 and the fourth sidewall 204.

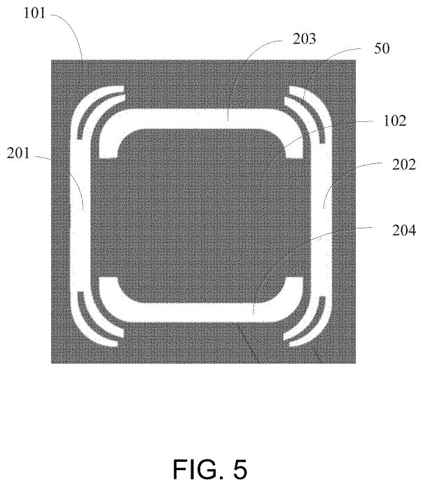

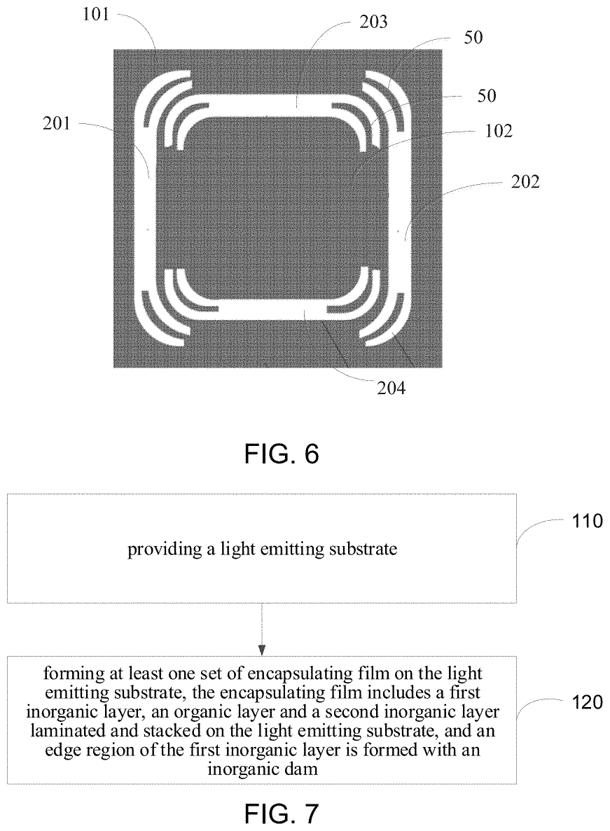

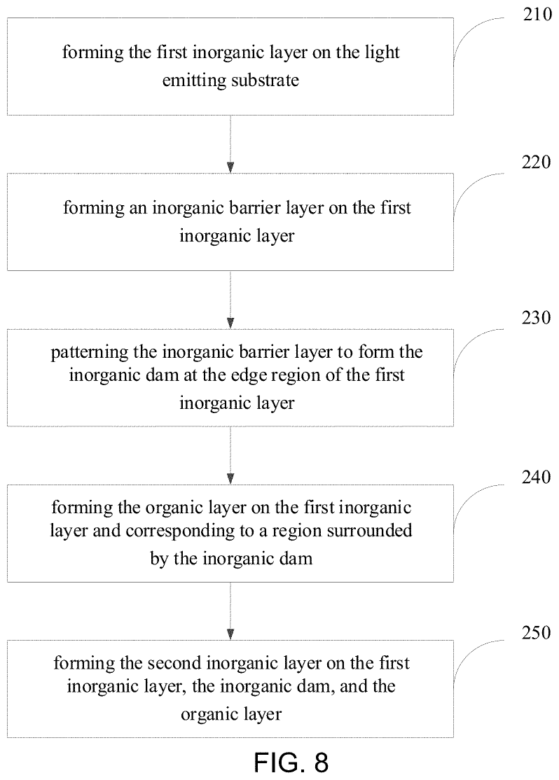

Please refer to FIG. 4 and accompany with FIG. 5 and FIG. 6. FIG. 4 is a schematic planar view showing an inorganic dam disposed on an OLED panel provided by a third embodiment of the present application, FIG. 5 is a schematic planar view showing an inorganic dam disposed on an OLED panel provided by a fourth embodiment of the present application, and FIG. 6 is a schematic planar view showing an inorganic dam disposed on an OLED panel provided by a fifth embodiment of the present application.

Any of the sidewalls includes a body portion and two bent portions disposed at both ends of the body portion. At least one opening 50 is formed in the bent portions of the first sidewall 201 and the second sidewall 202, and/or at least one opening 50 is formed in the bent portions of the third sidewall 203 and the fourth sidewall 204.

The inorganic dam 20 may be arranged as structures shown in FIG. 5 or FIG. 6. By providing the opening 50 in the bent portions of the sidewalls, a moisture and oxygen intrusion path of the devices on the light emitting substrate 10 is increased. Therefore, the moisture and oxygen barrier capability of the OLED panel is further improved. It should be noted that one or more openings 50 may be disposed in the bent portions of the first sidewall 201 and the second sidewall 202, and one or more openings 50 may be disposed in the bent portions of the third sidewall 203 and the fourth sidewall 204. which are determined according to actual conditions, and are not described more detail herein.

A distance between the bent portion of one of the sidewalls and a center point of the light emitting substrate 10 is different from a distance between the bent portion of another adjacent one of the sidewalls and the center point of the light emitting substrate 10. Specifically, the bent portions of the adjacent sidewalls are, for example, the first sidewall 201 and the third sidewall 203 which is adjacent to each other. A distance between the bent portion of the first sidewall 201 and a center point of the light emitting substrate 10 is greater than a distance between the bent portion of the third sidewall 203 and the center point of the light emitting substrate 10. The bent portion of the first sidewall 201 is disposed on the outer circumferential side of the bent portion of the third sidewall 203, thereby further improving the moisture and oxygen barrier capability of the light emitting substrate 10.

A material of the inorganic dam 20 is selected from a group consisting of silicon nitride, silicon carbonitride, and silicon oxide.

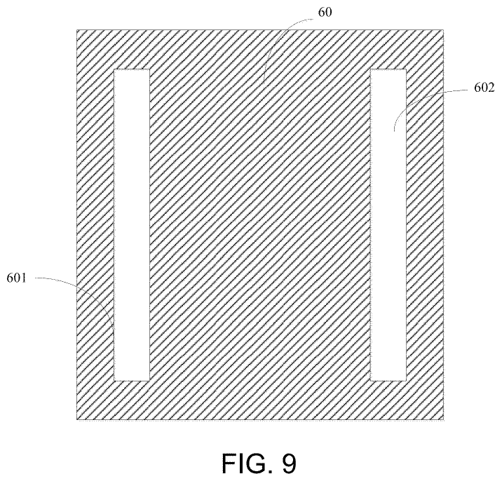

Please refer to FIG. 7. FIG. 7 is a schematic flow chart of a manufacturing method of an OLED device according to the present application.

The embodiment of the present application provides the manufacturing method of the OLED panel, including steps of:

Step 110, providing a light emitting substrate.

Step 120, forming at least one set of encapsulating film on the light emitting substrate, wherein the encapsulating film includes a first inorganic layer, an organic layer and a second inorganic layer laminated and stacked on the light emitting substrate, and wherein an edge region of the first inorganic layer is formed with an inorganic dam.

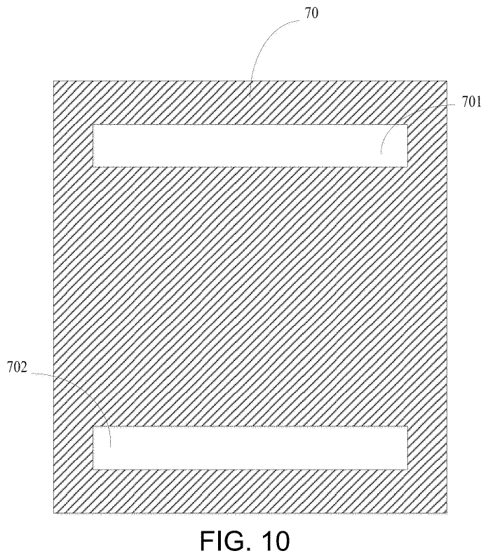

Please refer to FIG. 8. FIG. 8 is a schematic flow chart of forming at least one encapsulating film on alight emitting substrate in the manufacturing method of an OLED device according to the present application.

In this embodiment, the step 120 of forming the at least one set of encapsulating film on the light emitting substrate, wherein the encapsulating film includes the first inorganic layer, the organic layer and the second inorganic layer laminated and stacked on the light emitting substrate, and wherein the edge region of the first inorganic layer is formed with the inorganic dam which specifically includes the following steps of:

Step 210, forming the first inorganic layer on the light emitting substrate.

the light emitting substrate is transferred to a reaction chamber of a chemical vapor deposition apparatus to form the first inorganic layer which have a moisture and oxygen barrier capability.

Step 220, forming an inorganic barrier layer on the first inorganic layer.

Step 230, patterning the inorganic barrier layer to form the inorganic dam at the edge region of the first inorganic layer.

For example, an opening is first provided on the mask, which corresponds to an area of the inorganic dam. The inorganic material is then transferred on the first inorganic layer through the opening in the mask by using a chemical vapor deposition apparatus to form the inorganic dam at the edge region of the first inorganic layer.

Step 240, forming the organic layer on the first inorganic layer and corresponding to a region surrounded by the inorganic dam.

For example, the organic layer is formed by an inkjet printing process, and formed on the first inorganic layer and corresponding to the region surrounded by the inorganic dam, that is, the inorganic dam is disposed at the edge region of the first inorganic layer. A material of the organic layer may be selected from a group consisting of acrylic, epoxy, and silicone. A thickness of the inorganic dam can be slightly larger than a thickness of the organic layer, that can further improve the moisture and oxygen barrier capability of the OLED panel.

Step 250. forming the second inorganic layer on the first inorganic layer, the inorganic dam, and the organic layer.

For example, the light emitting substrate in step 240 is transferred to the reaction chamber of the chemical vapor deposition apparatus, and the second inorganic layer is formed on an upper surface of the inorganic dam and an upper surface of the organic layer by a chemical vapor deposition method.

The mask includes a first mask and a second mask, the step of patterning the inorganic barrier layer to form the inorganic dam at the edge region of the first inorganic layer, including steps of:

shielding a region of the first inorganic layer except the edge region of the first inorganic layer by the first mask, to form a first inorganic dam at the edge region of the first inorganic layer, and

shielding the first inorganic dam and a region of the first inorganic layer without forming the inorganic dam by the second mask, to form a second inorganic dam at the edge region of the first inorganic layer, wherein the first inorganic dam and the second inorganic dam surround the organic layer to form the inorganic dam.

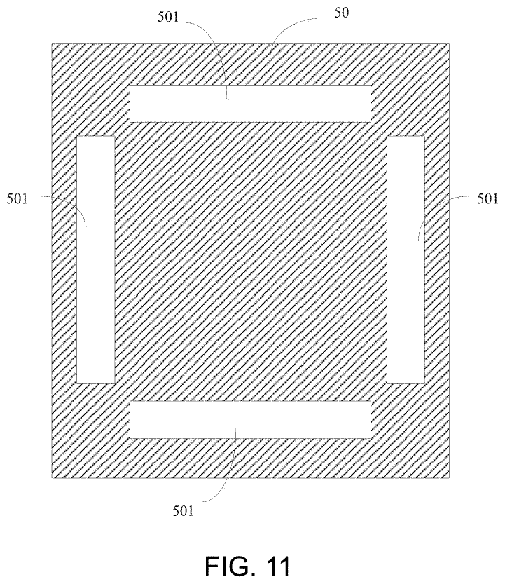

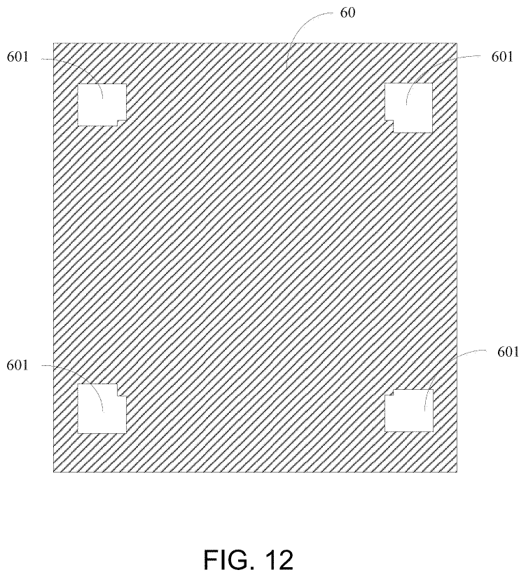

Please refer to FIG. 2 and accompany with FIG. 9 and FIG. 10, in a specific embodiment, a first opening area 601 and a second opening area 602 are formed on the first mask 60. The first opening area 601 corresponds to the first sidewall 201, and the second opening area 602 corresponds to the second sidewall 202. The first mask 60 is disposed above the light emitting substrate 10, and the region of the first inorganic layer 101 except the edge region of the first inorganic layer 101 is shielded by the first mask 60, to form the first inorganic dam at the edge region of the first inorganic layer 101. That is, the first sidewall 101 and the second sidewall 102 of the first inorganic dam.

A third opening area 701 and a fourth opening area 702 are formed on the second mask 70. The first opening area 701 corresponds to the third sidewall 203, and the second opening area 702 corresponds to the fourth sidewall 204. The second mask 70 is disposed above the light emitting substrate 10, the first sidewall 101, the second sidewall 102 and the region of the first inorganic layer 101 without forming the inorganic dam 20 are shielded by the second mask, to form the second inorganic dam at the edge region of the first inorganic layer, that is, the third sidewall 203 and the fourth sidewall 204 of the second inorganic dam. The first inorganic dam and the second inorganic dam surround the organic layer to form the inorganic dam.

Therefore, the step of patterning the inorganic barrier layer to form the inorganic dam at the edge region of the first inorganic layer includes the following steps of:

shielding a region of the first inorganic layer except the edge region of the first inorganic layer by a third mask to form the inorganic dam at the edge region of the first inorganic layer.

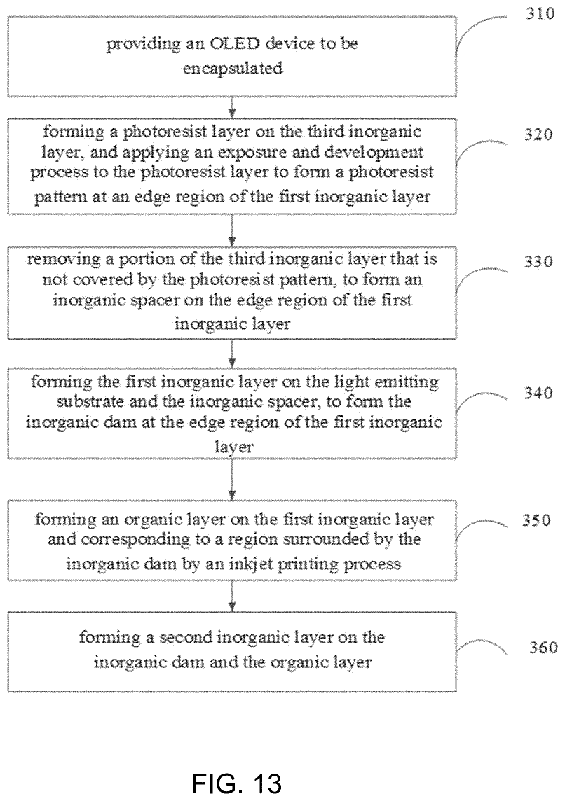

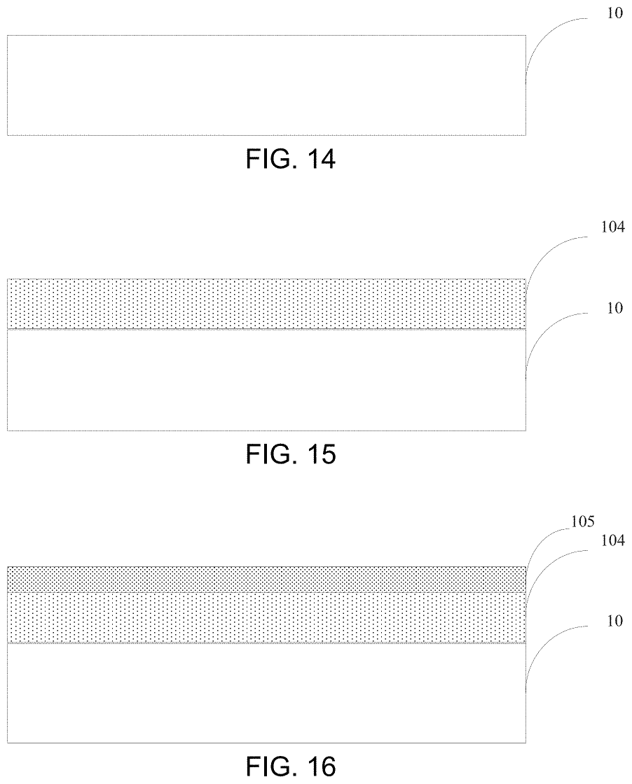

For the method of forming the inorganic dam 20, please accompany with FIG. 3, FIG. 11 and FIG. 12. FIG. 11 is a schematic structural view of a first mask provided by the second embodiment of the present application, and FIG. 12 is a schematic structural view of a second mask provided by the second embodiment of the present application, the specific embodiment is similar to the above embodiments, and is not described in detail herein again.

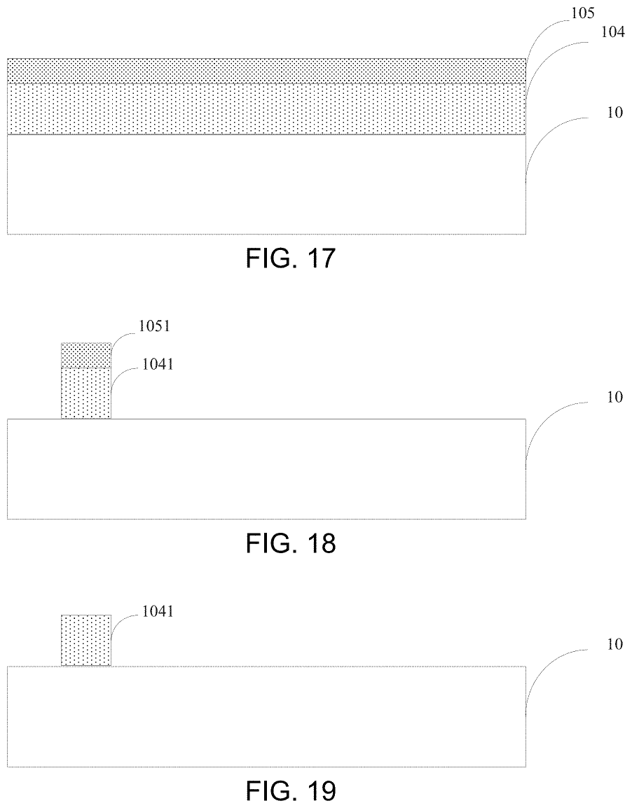

Please refer to FIG. 13. FIG. 13 is a schematic flow chart of forming a set of encapsulating film on a light emitting substrate in a manufacturing method of an OLED device according to the present application.

In this embodiment, step 120 “forming the at least one set of encapsulating film on the light emitting substrate, wherein the encapsulating film includes the first inorganic layer, the organic layer and the second inorganic layer laminated and stacked on the light emitting substrate, and wherein the edge region of the first inorganic layer is formed with the inorganic dam”, which includes the following steps of:

Step 310. providing an OLED device to be encapsulated.

Specifically, as shown in FIG. 15, the light emitting substrate 10 is transferred to a reaction chamber of a chemical vapor deposition apparatus, and a third inorganic layer 104 is formed on the light emitting substrate 10.

Step 320, forming a photoresist layer on the third inorganic layer, and applying an exposure and development process to the photoresist layer to form a photoresist pattern at an edge region of the first inorganic layer.

As shown in FIGS. 16, 17, and 18, the light emitting substrate 10 in which the third inorganic layer 104 has been formed in step 310 is used, and a photoresist layer 105 is formed on the third inorganic layer. For example, by a manner of spin coating, the photoresist layer 105 that has a thickness being about 2 to 3 microns is formed on the third inorganic layer 104. The photoresist layer then forms a photoresist pattern 1051 at the edge region of the first organic layer first inorganic layer 101 after UV curing, exposure to development process.

Step 330, removing a portion of the third inorganic layer that is not covered by the photoresist pattern, to form an inorganic spacer on the edge region of the first inorganic layer.

As shown in FIG. 18 and FIG. 19, a portion of the third inorganic layer 104 that is not covered by the photoresist pattern is removed by a dry etching process, and a portion of the third inorganic layer 104 that is covered by the photoresist pattern 1051 is retained, that is, the retained third inorganic layer 104 is an inorganic spacer 1041.

Step 340, forming the first inorganic layer on the light emitting substrate and the inorganic spacer, to form the inorganic dam at the edge region of the first inorganic layer.

Please refer to FIG. 20, the light emitting substrate 10 that is formed by the step 330 is transferred to a reaction chamber of a chemical vapor deposition apparatus. The first inorganic layer 101 is formed, and the first inorganic layer 101 is stacked on the inorganic spacer 1041 to form the inorganic dam 20 at the edge region of the organic layer.

It should be noted that, in the step 340, the third inorganic layer 104 that is not covered by the photoresist pattern 1051 needs to be removed by the dry etching process, to obtain the inorganic spacer 1041. The light emitting substrate 10 is then transferred to a hydrofluoroether solution and bathed for several hours to remove the photoresist pattern 1051. Preferably, the bathing time can be 2 hours. Then, the light emitting substrate 10 is transferred to the reaction chamber of the chemical vapor deposition apparatus, and the first inorganic layer 101 is deposited on the light emitting substrate 10 and the inorganic spacer 1041, and the first inorganic layer 101 and the inorganic spacer 1041 is stacked at an edge region of the organic layer 102 to form the inorganic dam 20.

Step 350, forming an organic layer on the first inorganic layer and corresponding to a region surrounded by the inorganic dam by an inkjet printing process.

As shown in FIG. 21, an organic layer 102 is formed on the first inorganic layer 101 and corresponding to a region surrounded by the inorganic dam 20 by an ink jet printing apparatus, that is, the inorganic dam 20 is disposed on an edge region of the first organic layer first inorganic layer 101. A material of the organic layer 102 may be selected from a group consisting of acrylic, epoxy, and silicone. A thickness of the inorganic dam 20 may be slightly larger than a thickness of the organic layer 102, and the inorganic dam 20 defines a boundary of the organic layer 102.

Step 360, forming a second inorganic layer on the inorganic dam and the organic layer.

As shown in FIG. 22, for example, still by the method of chemical vapor deposition, the light emitting substrate 10 that is formed by step 305 is transferred to the reaction chamber of the chemical vapor deposition apparatus, and a second inorganic layer 103 is formed on an upper surface of the inorganic dam 20 and an upper surface of the organic layer 102.

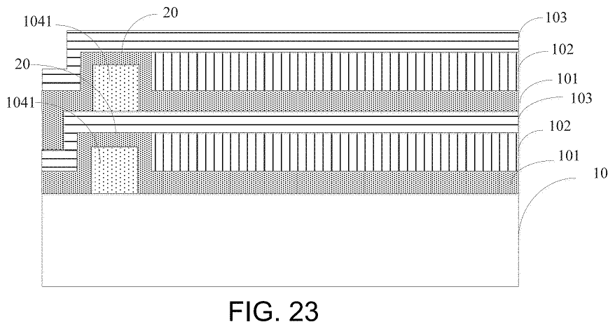

Please refer to FIG. 23. FIG. 23 is a schematic cross-sectional view of an OLED panel provided by the second embodiment of the present application. Two sets of films can be formed on the light emitting substrate 10. The steps for forming each set of films can refer to the previous embodiments, and the details are not described herein again.

In this embodiment, the inorganic dam 20 is formed at the edge region of the first inorganic layer 101, which improves the moisture and oxygen barrier capability of the OLED panel, thereby prolonging the service life of the OLED panel.

The OLED panel and the manufacturing method provided by the embodiments of the present application are described in detail. The principles and embodiments of the present application are set forth in the specific examples, and the description of the above embodiments is only for the purpose of understanding the present application. In the meantime, those skilled in the art will be able to generate variations in the specific embodiments and change the scope of application in view of the idea of the present application, and the contents of the present specification should not be construed as limitations of the present application.

1. An organic light-emitting diode (OLED) panel, comprising:
a light emitting substrate, and at least one set of encapsulating film disposed on the light emitting substrate;
wherein the encapsulating film comprises a first inorganic layer disposed on the light emitting substrate, an inorganic dam disposed at an edge region of the first inorganic layer, an organic layer disposed on the first inorganic layer and surrounded by the inorganic dam, and a second inorganic layer disposed on the organic layer and covering the first inorganic layer, the organic layer and the inorganic dam;
wherein the inorganic dam comprises a plurality of sidewalls, the sidewalls comprise a first sidewall and a second sidewall opposite to each other, and a third sidewall and a fourth sidewall separately disposed on two opposite sides of the first sidewall, wherein the third sidewall and the fourth sidewall are disposed opposite to each other;
wherein a material of the inorganic dam is selected from a group consisting of silicon nitride, silicon carbonitride, and silicon oxide.

2. The OLED panel according to claim 1, wherein the first sidewall is connected to the third sidewall and the fourth sidewall, and the second sidewall is connected to the third sidewall and the fourth sidewall, such that the inorganic dam surrounds the organic layer at the edge region of the first inorganic layer.

3. The OLED panel according to claim 1, wherein the inorganic dam further comprises a first connecting arm, a second connecting arm, a third connecting arm and a fourth connecting arm;
the first connecting arm is connected to the first sidewall and the third sidewall;
the second connecting arm is connected to the first sidewall and the fourth sidewall;
the third connecting arm is connected to the second sidewall and the third sidewall; and
the fourth connecting arm is connected to the second sidewall and the fourth sidewall.

4. The OLED panel according to claim 1, wherein any one of the sidewalls comprises a body portion and two bent portions disposed at both ends of the body portion; and
wherein at least one opening is formed in the bent portions of the first sidewall and the bent portions of the second sidewall; and/or
at least one opening is formed in the bent portions of the third sidewall and the bent portions of the fourth sidewall.

5. The OLED panel according to claim 4, wherein a distance between the bent portion of one of the sidewalls and a center point of the light emitting substrate is different from a distance between the bent portion of another adjacent one of the sidewalls and the center point of the light emitting substrate.

6. The OLED panel according to claim 1, wherein a material of the organic layer is selected from a group consisting of acrylic, epoxy, and silicone.

7. An organic light-emitting diode (OLED) panel, comprising:
a light emitting substrate, and at least one set of encapsulating film disposed on the light emitting substrate;
wherein the encapsulating film comprises a first inorganic layer disposed on the light emitting substrate, an inorganic dam disposed at an edge region of the first inorganic layer, an organic layer disposed on the first inorganic layer and surrounded by the inorganic dam, and a second inorganic layer disposed on the organic layer and covering the first inorganic layer, the organic layer and the inorganic dam.

8. The OLED panel according to claim 7, wherein the inorganic dam comprises a plurality of sidewalls, the sidewalls comprise a first sidewall and a second sidewall opposite to each other, and a third sidewall and a fourth sidewall separately disposed on two opposite sides of the first sidewall, wherein the third sidewall and the fourth sidewall are disposed opposite to each other.

9. The OLED panel according to claim 8, wherein the first sidewall is connected to the third sidewall and the fourth sidewall, and the second sidewall is connected to the third sidewall and the fourth sidewall, such that the inorganic dam surrounds the organic layer at the edge region of the first inorganic layer.

10. The OLED panel according to claim 8, wherein the inorganic dam further comprises a first connecting arm, a second connecting arm, a third connecting arm and a fourth connecting arm;
the first connecting arm is connected to the first sidewall and the third sidewall;
the second connecting arm is connected to the first sidewall and the fourth sidewall;
the third connecting arm is connected to the second sidewall and the third sidewall; and
the fourth connecting arm is connected to the second sidewall and the fourth sidewall.

11. The OLED panel according to claim 8, wherein any one of the sidewalls comprises a body portion and two bent portions disposed at both ends of the body portion; and
wherein at least one opening is formed in the bent portions of the first sidewall and the bent portions of the second sidewall; and/or
at least one opening is formed in the bent portions of the third sidewall and the bent portions of the fourth sidewall.

12. The OLED panel according to claim 11, wherein a distance between the bent portion of one of the sidewalls and a center point of the light emitting substrate is different from a distance between the bent portion of another adjacent one of the sidewalls and the center point of the light emitting substrate.

13. The OLED panel according to claim 7, wherein a material of the inorganic dam is selected from a group consisting of silicon nitride, silicon carbonitride, and silicon oxide.

14. A manufacturing method of an organic light-emitting diode (OLED) panel, comprising steps of:
providing a light emitting substrate; and
forming at least one set of encapsulating film on the light emitting substrate, wherein the encapsulating film comprises a first inorganic layer, an organic layer and a second inorganic layer laminated and stacked on the light emitting substrate, and wherein an edge region of the first inorganic layer is formed with an inorganic dam.

15. The manufacturing method according to claim 14, wherein the step of forming the at least one set of encapsulating film on the light emitting substrate comprises steps of:
forming the first inorganic layer on the light emitting substrate;
forming an inorganic barrier layer on the first inorganic layer;
patterning the inorganic barrier layer to form the inorganic dam at the edge region of the first inorganic layer;
forming the organic layer on the first inorganic layer and corresponding to a region surrounded by the inorganic dam; and
forming the second inorganic layer on the first inorganic layer, the inorganic dam, and the organic layer.

16. The manufacturing method according to claim 15, wherein the step of patterning the inorganic barrier layer to form the inorganic dam at the edge region of the first inorganic layer comprises steps of:
shielding a region of the first inorganic layer except the edge region of the first inorganic layer by a first mask, to form a first inorganic dam at the edge region of the first inorganic layer; and
shielding the first inorganic dam and a region of the first inorganic layer without forming the inorganic dam by a second mask, to form a second inorganic dam at the edge region of the first inorganic layer, wherein the first inorganic dam and the second inorganic dam surround the organic layer to form the inorganic dam.

17. The manufacturing method according to claim 15, wherein the step of patterning the inorganic barrier layer to form the inorganic dam at the edge region of the first inorganic layer comprises step of:
shielding a region of the first inorganic layer except the edge region of the first inorganic layer by a third mask to form the inorganic dam at the edge region of the first inorganic layer.
